(19) United States
(12) Patent Application Publication
(10) Pub. No.: US 2026/0020248 A1
(43) Pub. Date: Jan. 15, 2026

(54) MAGNETIC MEMORY DEVICE INCLUDING MAGNETIC DOMAIN WALL PINNING SITE AND MEMORY APPARATUS INCLUDING THE SAME

(71) Applicant: Samsung Electronics Co., Ltd., Suwon-si (KR)

(72) Inventors: Atsushi OKADA, Suwon-si (KR); Soichiro MIZUSAKI, Suwon-si (KR); Unghwan PI, Suwon-si (KR); Naoki HASE, Suwon-si (KR)

(73) Assignee: Samsung Electronics Co., Ltd., Suwon-si (KR)

(21) Appl. No.: 18/954,992

(22) Filed: Nov. 21, 2024

(30) Foreign Application Priority Data
Jul. 10, 2024 (KR) 10-2024-0091357

(51) Int. Cl. H10B 61/00; G11C 11/16; H10N 50/10; H10N 50/80

(52) U.S. Cl. CPC H10B 61/20; G11C 11/161; G11C 11/1675; H10N 50/10; H10N 50/80

(57) ABSTRACT

A magnetic memory device includes a magnetic tunneling junction including a free layer, a tunnel barrier layer, and a pinned layer, a spin orbit torque layer at an opposite side of the tunnel barrier layer with respect to the free layer to change a magnetization direction of the free layer, and a domain wall pinning site configured to fix the pinned domain wall. The free layer includes a first region having a first width and in which a movable domain wall moves, and second and third regions extending from both end portions of the first region and respectively having a second width and a third width, which are greater than the first width. A domain wall pinning site is in the third region of the free layer and fix a pinned domain wall among the movable domain wall and the pinned domain wall, which are formed in an initialization process.

### CROSS-REFERENCE TO RELATED APPLICATION

This application claims the benefit of Korean Patent Application No. 10-2024-0091357, filed on Jul. 10, 2024, in the Korean Intellectual Property Office, the disclosure of which is incorporated herein in its entirety by reference.

### BACKGROUND

### 1. Field

The disclosure relates to magnetic memory devices having a pinning site and memory devices including the magnetic memory.

### 2. Description of the Related Art

Magnetic memory devices, such as magnetic random access memory (MRAM), are memory devices that store data by utilizing changes in the resistance of magnetic tunnel junction elements. The resistance of a magnetic tunnel junction element varies depending on the magnetization direction of a free layer. For example, when the magnetization direction of a free layer is the same as the magnetization direction of a pinned layer, a magnetic tunnel junction element may have a low resistance value, and when the magnetization directions are opposite to each other, the magnetic tunnel junction element may have a high resistance value. When such properties are utilized in a memory device, for example, the magnetic tunneling junction element when having a low resistance value may represent data ‘0’, and the magnetic tunneling junction element when having a high resistance value may represent data ‘1’.

This magnetic memory device may have non-volatility, may operate at higher speed, and may have higher durability. For example, spin-transfer torque-magnetic MRAM (STT-MRAM) that is currently in mass production may have an operating speed of about 5 nsec to about 100 nsec and may also have excellent data retention of 10 years or more. Furthermore, as the spin polarization direction of spin-orbit torque (SOT)-MRAM is perpendicular to a magnetization direction, SOT-MRAM may have a very fast operating speed of 5 nsec or less, which is faster than that of STT-MRAM. Furthermore, the SOT-MRAM may have more stable durability because a write current path and a read current path are different from each other.

A domain wall exists between two magnetic domains with different magnetization directions in a free layer, and when current flows in the free layer, the magnetization directions of two magnetic domains vary, and the domain wall moves accordingly.

### SUMMARY

Some example embodiments provide magnetic memory devices having a simple structure and memory devices adopting the same.

Some example embodiments provide magnetic memory devices with a reduced size and memory devices adopting the same.

Additional aspects will be set forth in part in the description which follows and, in part, will be apparent from the description, or may be learned by practice of the presented example embodiments.

According to an aspect of the disclosure, a magnetic memory device includes a free layer including a movable domain wall and a pinned domain wall, a tunnel barrier layer, a pinned layer on the tunnel barrier layer, the pinned layer configured to form a magnetic tunneling junction with the free layer and the tunnel barrier layer, a spin orbit torque layer arranged at an opposite side of the tunnel barrier layer with respect to the free layer and configured to change the magnetization direction of the free layer, and a domain wall pinning site configured to fix the pinned domain wall. The free layer includes a first region, a second region, and a third region, the first region being an area having a first width and in which the movable domain wall moves, the second and third regions extending from both end portions of the first region, respectively, the second and third regions having a second width and a third width, respectively, the second and third widths being greater than the first width, and the domain wall pinning site is in the third region of the free layer.

In an example embodiment, the domain wall pinning site may include a notch recessed from an edge on at least one side in a width direction of the third region. In an example embodiment, the notch comprises a pair of notches on edges of both sides in the width direction of the third region and the pair of notches face each other in the width direction. In an example embodiment, the spin orbit torque layer may be exposed by the notch.

In an example embodiment, the domain wall pinning site may include a doping area extending inwardly from an edge on at least one side in a width direction of the third region and doped with impurities. In an example embodiment, the impurities may include a nonmagnetic heavy element. In an example embodiment, the impurities may include at least one of Ta, W, Pt, or Au. In an example embodiment, the doping area may include a pair of doping areas on edges of both sides in the width direction of the third region and the pair of doping regions face each other in the width direction.

In an example embodiment, the domain wall pinning site may include a plurality of domain wall pinning sites and the plurality of domain wall pinning sites are in the third region along a longitudinal direction. In an example embodiment, the plurality of domain wall pinning sites may include at least one of a notch recessed from an edge on at least one side in the width direction of the third region, or a doping area extending inwardly from an edge on at least one side in the width direction of the third region and doped with impurities.

In an example embodiment, the domain wall pinning site may include a recess portion, and the recess portion is across the third region in the width direction and recessed to the spin orbit torque layer.

In an example embodiment, the domain wall pinning site may include a doping area, and the doping area is across the third region in the width direction and doped with impurities including a nonmagnetic heavy element.

According to another aspect of the disclosure, a method of initializing a magnetic memory device includes preparing the magnetic memory device, the magnetic memory device including a free layer, a tunnel barrier layer, a pinned layer on the tunnel barrier layer and configured to form a magnetic tunneling junction with the free layer and the tunnel barrier layer, a spin orbit torque layer at an opposite side of the tunnel barrier layer with respect to the free layer and configured to change a magnetization direction of the free layer, and a domain wall pinning site, wherein the free layer may include a first region, a second region, and a third region, the first region being an area having a first width, the second and third regions extending from both end portions of the first region, respectively, the second and third regions having a second width and a third width, respectively, the second and third width being greater than the first width, and a domain wall pinning site is in the third region of the free layer, forming a movable domain wall between the first region and the second region by applying a pulse voltage to the free layer and the spin orbit torque layer within a magnetic field, and fixing a pinned domain wall to the domain wall pinning site.

In an example embodiment, the pulse voltage may be applied multiple times.

According to another aspect of the disclosure, a memory device includes a plurality of memory cells. The plurality of memory cell includes the magnetic memory device described above and a switching element connected to the magnetic memory device.

### BRIEF DESCRIPTION OF THE DRAWINGS

These and/or other aspects will become apparent and more readily appreciated from the following description of some example embodiments, taken in conjunction with the accompanying drawings in which:

FIG. 1 is a schematic cross-sectional view of a magnetic memory device according to an example embodiment;

FIG. 2 is a schematic plan view of a magnetic memory device according to an example embodiment;

FIG. 3 is a schematic plan view of a magnetic memory device according to an example embodiment;

FIG. 4 is a side view showing a notch according to an example embodiment;

FIG. 5 is a side view showing a notch according to an example embodiment;

FIG. 6 illustrates a magnetically switched state in a magnetic memory device according to an example embodiment;

FIG. 7 is a schematic plan view of a magnetic memory device according to an example embodiment;

FIG. 8 is a schematic plan view of a magnetic memory device according to an example embodiment;

FIG. 9 is a schematic plan view of a magnetic memory device according to an example embodiment;

FIG. 10 is a schematic plan view of a magnetic memory device according to an example embodiment;

FIG. 11 is a schematic plan view of a magnetic memory device according to an example embodiment;

FIG. 12 is a schematic configuration view of a memory device including a magnetic memory device according to an example embodiment; and

FIG. 13 is a conceptual view schematically showing a device architecture applicable to electronic apparatuses according to example embodiments.

### DETAILED DESCRIPTION

Reference will now be made in detail to example embodiments, examples of which are illustrated in the accompanying drawings, wherein like reference numerals refer to like elements throughout. In this regard, the disclosed example embodiments may have different forms and should not be construed as being limited to the descriptions set forth herein. Accordingly, the disclosed example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

In magnetic memory devices, a domain wall exists at a boundary between two magnetic domains with different magnetization directions in a free layer. When current flows in the free layer, the magnetization directions of the two magnetic domains vary, and the domain wall moves accordingly. Even if magnetic tunneling junction structure is formed, a domain wall does not form in the free layer. Therefore, in magnetic memory devices according to the related art, a magnetic field generation layer is provided to form a domain wall in the free layer. In order for the magnetic field generation layer to be properly coupled with the free layer, a sufficiently thick and large magnetic field generation layer is required or desired, which may complicate the structure of the magnetic memory device and may also have a detrimental effect on reducing the size of the magnetic memory device.

Hereinafter, some example embodiments of a magnetic memory devices having a simple structure and some example embodiments of a magnetic memory device with a reduced size are described with reference to the accompanying drawings.

Throughout the drawings, like reference numerals denote like elements, and sizes of components in the drawings may be exaggerated for convenience of explanation and clarity. Furthermore, as embodiments described below are examples, other modifications may be produced from the disclosed example embodiments.

When a constituent element is disposed “above” or “on” to another constituent element, the constituent element may include not only an element directly contacting and disposed on the other constituent element, but also an element disposed above the other constituent element in a non-contact manner. As used herein, the singular forms “a,” “an,” and “the” are intended to include the plural forms as well, unless the context clearly indicates otherwise. Furthermore, it will be further understood that the terms “comprises” and/or “comprising” used herein specify the presence of stated features or elements, but do not preclude the presence or addition of one or more other features or elements.

The use of the terms “a,” “an,” “the,” and similar referents in the context of describing the disclosure is to be construed to cover both the singular and the plural. Also, the operations of all methods described herein can be performed in any suitable order unless otherwise indicated herein or otherwise clearly contradicted by context. The disclosure is not limited to the described order of the steps.

Furthermore, terms such as “ . . . portion,” “ . . . unit,” “ . . . module,” and “ . . . block” stated in the disclosure may signify a unit configured to process at least one function or operation and the unit may be embodied by hardware, software, or a combination of hardware and software.

Furthermore, the connecting lines, or connectors shown in the various figures presented are intended to represent functional relationships and/or physical or logical couplings between the various elements. It should be noted that many alternative or additional functional relationships, physical connections or logical connections may be present in a practical device.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

The use of any and all examples, or language (e.g., “such as”) provided herein, is intended merely to better illuminate the disclosure and does not pose a limitation on the scope of the disclosure unless otherwise claimed.

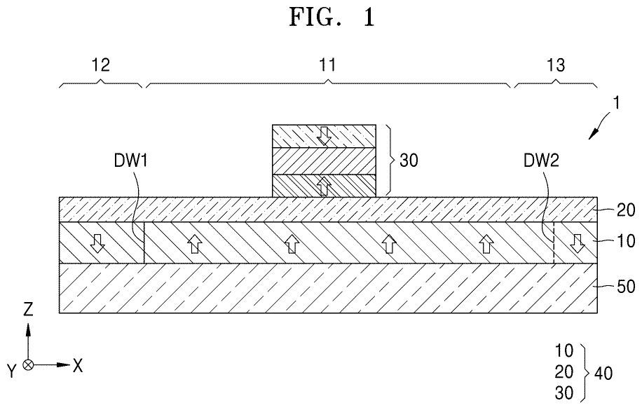

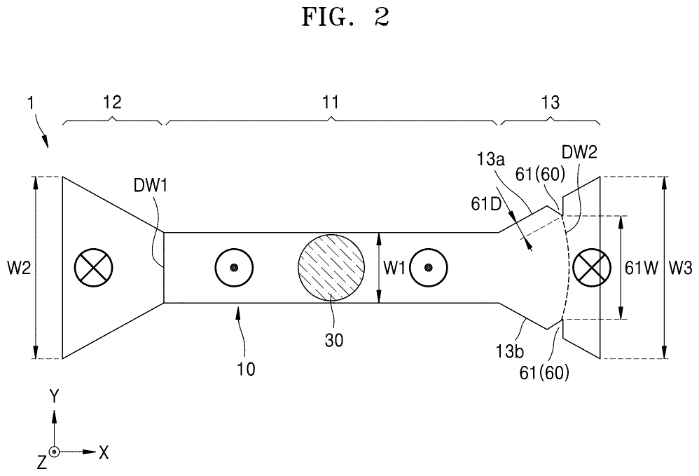

FIG. 1 is a schematic cross-sectional view of a magnetic memory device 1 according to an example embodiment. FIG. 2 is a schematic plan view of the magnetic memory device 1 according to an example embodiment. In the following descriptions, a longitudinal direction of each layer is represented by X, a width direction perpendicular to the longitudinal direction X is represented by Y, and a thickness direction perpendicular to the longitudinal direction X and the width direction Y is represented by Z.

Referring to FIG. 1, the magnetic memory device 1 may include a free layer 10, a tunnel barrier layer 20, and a pinned layer 30, which are stacked on each other to form a magnetic tunneling junction (MTJ), and a spin orbit torque layer 50 for changing a magnetization direction of the free layer 10. The tunnel barrier layer 20 is disposed on the free layer 10, and the pinned layer 30 is disposed on the tunnel barrier layer 20. The spin orbit torque layer 50 is disposed on the opposite side of the tunnel barrier layer 20 with respect the free layer 10. In other words, the spin orbit torque layer 50 faces the tunnel barrier layer 20 with the free layer 10 therebetween. The free layer 10, the tunnel barrier layer 20, and the pinned layer 30 form magnetic tunneling junction. The free layer 10, the tunnel barrier layer 20, and the pinned layer 30 may be referred to as a tunneling magnetic resistance layer 40.

The free layer 10 may include a first region 11, a second region 12, and a third region 13. The first region 11 is a region in which a movable domain wall DW1 described below moves. As an example, the planar shape of the first region 11 may be a rectangular shape. The first region 11 has a first width W1. The second region 12 and the third region 13 are regions extending from both end portions of the longitudinal direction X of the first region 11, respectively. The second region 12 and the third region 13 have a second width W2 and a third width W3, respectively. The second width W2 and the third width W3 are greater than the first width W1. In an example embodiment, the second width W2 of the second region 12 may gradually increase away from an edge on one side of the first region 11. The third width W3 of the third region 13 may gradually increase away from an edge on the other side of the first region 11. Although FIG. 2 illustrates that the second region 12 and the third region 13 each have a trapezoidal shape, as an example, the disclosure is not limited thereto. For example, the second width W2 of the second region 12 and the third width W3 of the third region 13 may each be constant. In other words, the second region 12 and the third region 13 may each have a rectangular shape. Although it is not illustrated, the second region 12 and the third region 13 may each have various planar shapes in which the second and third widths W2 and W3 are greater than the first width W1 of the first region 11. The second width W2 and the third width W3 may be the same as each other or different from each other. A domain wall pinning site or pinning site 60 at which a pinned domain wall DW2 is fixed, as described below, is provided in the third region 13.

The free layer 10 and the pinned layer 30 may be formed of a ferromagnetic metal material. For example, the free layer 10 and the pinned layer 30 may each include at least one ferromagnetic material. For example, the free layer 10 and the pinned layer 30 may each include at last one of iron (Fe), cobalt (Co), nickel (Ni), manganese (Mn), a Fe-containing alloy, a Co-containing alloy, a Ni-containing alloy, a Mn-containing alloy, or a Heusler alloy. The free layer 10 and the pinned layer 30 may have a higher perpendicular magnetic anisotropy (PMA). The PMA energy of the free layer 10 and the pinned layer 30 may exceed out-of-plane demagnetization energy. In this case, the magnetic moments of the free layer 10 and the pinned layer 30 may be stabilized in the thickness direction Z perpendicular to a plane, for example an X-Y plane. The free layer 10 and the pinned layer 30 may be formed of the same material or different materials. For example, for the magnetization direction of the free layer 10 to be more easily changed by a lower current, the free layer 10 may be doped with at least one nonmagnetic metal. For example, the free layer 10 may be doped with at least one of Mg, Ru, Ir, Ti, Zn, Ga, Ta, Al, Mo, Zr, Sn, W, Sb, V, Nb, Cr, Ge, Si, Hf, Tb, Sc, Y, Rh, in, Ca, Sr, Ba, Be, V, Li, Cd, Pb, Ga, or Mo.

Although it is not illustrated, for the movable domain wall DW1 to operate at higher speed and a lower current density, the free layer 10 may include synthetic anti-ferromagnetic (SAF) coupling layer. For example, the free layer 10 may include a first free layer, a second free layer, and an SAF coupling layer inserted therebetween. Accordingly, the free layer 10 may have a magnetic structure in which the magnetization directions of the first and second free layers are opposite to each other. The SAF coupling layer may include, for example, nonmagnetic metal, such as Ru or Ir. The first free layer and the second free layer may form an antiferromagnetic material through a medium of the SAF coupling layer by Ruderman-Kittel-Kasuya-Yosida (RKKY) interaction. In other words, when the magnetization direction of the first free layer and the magnetization direction of the second free layer are opposite to each other (e.g., anti-parallel), a stable state may be obtained. The SAF coupling layer may have an appropriate thickness range to mediate the RKKY interaction. For example, the thickness of the SAF coupling layer may be about 0.5 nm or more and about 3 nm or less.

The tunnel barrier layer 20 may act as a tunnel barrier for magnetic tunneling junction. The tunnel barrier layer 20 may include oxide. The tunnel barrier layer 20 may include a crystalline magnesium (Mg) oxide. For example, the tunnel barrier layer 20 may include MgO, MgAl₂O₄, or MgTiOx. However, the disclosure is not limited thereto, and for example, the tunnel barrier layer 20 may include boron nitride (BN).

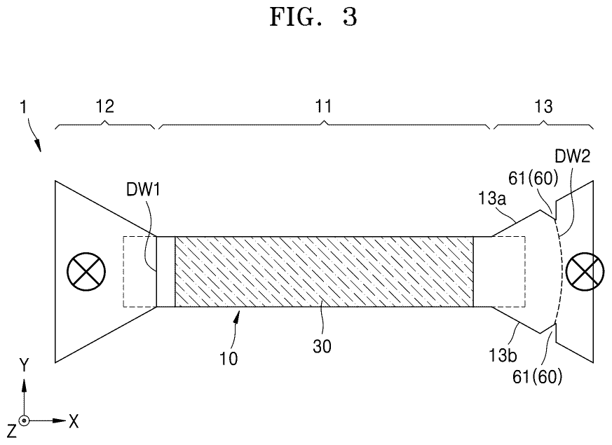

The pinned layer 30 may be located on the tunnel barrier layer 20 such that at least a part of the pinned layer 30 overlaps the first region 11 of the free layer 10. In FIG. 2, the pinned layer 30 is disposed within the first region 11. Although FIG. 2 illustrates that the pinned layer 30 has a circular planar shape, the planar shape of the pinned layer 30 is not limited thereto. The size and the shape of pinned layer 30 are not limited to those illustrated in FIG. 2. For example, as illustrated by a solid line in FIG. 3, the pinned layer 30 may has a rectangular shape with almost the same size as the first region 11. Furthermore, as illustrated by a dashed line in FIG. 3, the pinned layer 30 may partially overlap the second region 12 and/or the third region 13.

The pinned layer 30 may have a pinned magnetization direction. The magnetization direction of the pinned layer 30 may not be changed once set. The pinned layer 30 may have a single layer structure having a ferromagnetic material layer. The pinned layer 30 may have a multilayer structure including the SAF coupling layer. For example, the pinned layer 30 may include a first pinned layer, a second pinned layer, and an SAF coupling layer inserted therebetween. Accordingly, the pinned layer 30 may have a magnetic structure in which the magnetization directions of the first pinned layer and the second pinned layer are opposite to each other. The SAF coupling layer may include, for example, nonmagnetic metal, such as Ru or Ir. The first pinned layer and the second pinned layer may form an antiferromagnetic material through a medium of the SAF coupling layer by the RKKY interaction. In other words, when the magnetization direction of the first pinned layer and the magnetization direction of the second pinned layer are opposite to each other (e.g., anti-parallel), a stable state may be obtained. The SAF coupling layer may have an appropriate thickness range to mediate the RKKY interaction. For example, the thickness of the SAF coupling layer may be about 0.5 nm or more and about 3 nm or less. FIG. 1 illustrates the pinned layer 30 of a multilayer structure. In this case, the magnetization direction of the pinned layer 30 may be represented by the magnetization direction of a layer adjacent to the tunnel barrier layer 20.

When the free layer 10 has a multilayer structure, the representative magnetization direction is the magnetization direction of a layer adjacent to the tunnel barrier layer 20. The free layer 10 may have variable magnetization directions. The magnetization direction of the free layer 10 may be changed according to a current applied to the spin orbit torque layer 50. For example, the free layer 10 may be magnetized in a +Z direction or a −Z direction depending on the direction of the current applied to the spin orbit torque layer 50.

The spin orbit torque layer 50 may induce spin orbit torque by a current flowing therein. In an example embodiment, the spin orbit torque layer 50 may include non-magnetic heavy metal with atomic number of 30 or more. For example, the spin orbit torque layer 50 may include at least one of iridium (Ir), ruthenium (Ru), tantalum (Ta), platinum (Pt), palladium (Pd), bismuth (Bi), titanium (Ti), tungsten (W), or an alloy thereof, but the disclosure is not limited thereto.

In an example embodiment, the spin orbit torque layer 50 may have a two-layer structure of an orbital Hall conductance (OHC) material layer/a conversion layer. In order to obtain an operating speed of about 1 nanosecond in the magnetic memory device 1 adopting the spin orbit torque layer 50, an operating current density needs to be decreased. To do so, the amount of spin current generated in the spin orbit torque layer 50 needs to be increased. In the spin-orbit torque layer 50, it is necessary or desirable to increase spin Hall angle (SHA), which is an efficiency of charge current being converted into spin current by the spin Hall effect, and spin Hall conductance (SHC), which is an amount of spin current that a spin-orbit torque material is able to generate. When a current is supplied to an OHC material layer having OHC higher than SHC indicated by Pt that is a general spin orbit torque material, an orbit current is generated. The orbit current may be converted into a spin current by the conversion layer. As the spin current is generated by the conversion layer, a large spin current may be generated by the spin orbit torque layer 50 having a two-layer structure of an OHC material layer/a conversion layer, and thus, a domain wall movement or magnetic switching with respect to the free layer 10 is possible at a low operating current density. The OHC material layer may include an element having a large OHC or an alloy thereof. For example, the OHC material layer may include at least one of Ir, IrMn, PtMn, V, Cr, Mn, Nb, Mo, Ru, Ta, W, or Re. The conversion layer may include at least one of Pt, or Tb, Gd, Sm, or Dy, which is rare-earth element.

In the related art, even when the tunneling magnetic resistance layer 40 and the spin orbit torque layer 50 are formed according to a manufacturing process, no domain wall exists in the free layer 10 because the free layer 10 is not magnetized, that is, the free layer 10 is in a no magnetic domain state. In the magnetic memory devices according to the related art, in order to form a magnetic domain and a domain wall, a magnetic field generation structure is provided to form a magnetic field locally in the second region 12 and the third region 13. This structure complicates the structure of the magnetic memory device, increases the manufacturing cost of the magnetic memory device, and is also disadvantageous for reducing the size of the magnetic memory device.

According to some example embodiments of the disclosure, after the tunneling magnetic resistance layer 40 and the spin orbit torque layer 50 are formed, two domain walls DW1 and DW2 are generated in the free layer 10 through an initialization process. An example embodiment of an initialization method is described below.

First, the tunneling magnetic resistance layer 40 and the spin orbit torque layer 50 illustrated in FIGS. 1 and 2 are formed. Next, a magnetic field is applied to the tunneling magnetic resistance layer 40 and the spin orbit torque layer 50 in a direction parallel to a movement direction of a domain wall. In this state, a pulse voltage is applied to the free layer 10 and the spin orbit torque layer 50. In a non-limiting example, the intensity of the magnetic field is about 10 mT, and the pulse voltage is about 16 V. Magnetic domains are generated in the free layer 10 by the magnetic field and pulse voltage. For example, referring to FIGS. 1 and 2, a magnetic domain magnetized in the +Z direction is generated in the first region 11, and a magnetic domain magnetized in the −Z direction is generated in the second region 12 and the third region 13. The two domain walls DW1 and DW2 are generated between three magnetic domains.

The domain wall DW1 is located around a boundary between the first region 11 and the second region 12. The domain wall DW2 is located around a boundary between the first region 11 and the third region 13. The domain wall DW1 is used as a movable domain wall that moves in the first region 11 as current flows in the spin orbit torque layer 50. Accordingly, the domain wall DW1 is also referred to as the movable domain wall DW1. The domain wall DW2 needs to be fixed without moving toward the first region 11 even when current flows in the spin orbit torque layer 50. To fix the domain wall DW2 to the third region 13, as described above, a pinning site 60 is provided in the third region 13. The pinning site 60 may be implemented in various manners to fix the domain wall DW2 without moving.

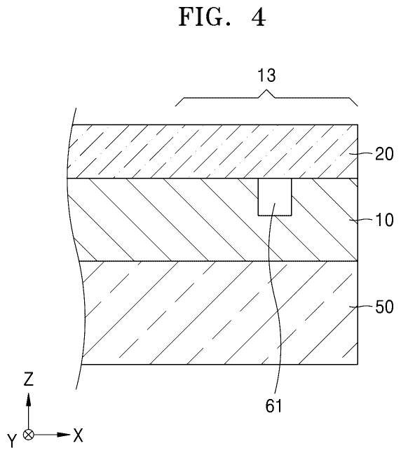

In an example embodiment, referring to FIG. 2, the pinning site 60 may include a notch 61. The notch 61 may be recessed into the third region 13 from an edge 13a on one side in the width direction Y of the third region 13. The notch 61 may be formed in a direction perpendicular to a direction of magnetic field lines in the third region 13, for example, a direction perpendicular to the edge 13a on one side in the third width W3 of the third region 13. FIG. 4 is a side view showing the notch 61 according to an example embodiment. As illustrated in FIG. 4, the thickness of the notch 61 may be less than the thickness of the free layer 10. In other words, the notch 61 may be partially recessed in the thickness direction Z from the upper surface of the free layer 10.

The energy of a domain wall increases as the length (length in the width direction Y) of the domain wall increases. As the width of the third region 13 is decreased by the notch 61, the energy of the domain wall DW2 generated in the initialization process decreases closer to the notch 61, and thus, the energy is reduced or minimized in an area where the notch 61 is formed. Accordingly, when the domain wall DW2 reaches near the notch 61, the energy of the domain wall DW2 is stabilized, and the domain wall DW2 does no longer move in the longitudinal direction X and is fixed in the vicinity of the notch 61. The domain wall DW2 is also referred to as the pinned domain wall DW2.

The notch 61 may be formed on at least one of the two edges 13a and 13b in the width direction Y of the third region 13. In other words, the notch 61 may be formed on any one of the two edges 13a and 13b in the width direction Y of the third region 13, or as illustrated in FIG. 2, the notch 61 may be formed as a pair of notches on both sides in the width direction Y of the third region 13, respectively, to face each other in the width direction Y. By adopting a pair of notches 61, the pinned domain wall DW2 may be more easily fixed.

The width 61W of the third region 13, which is reduced by the notch 61, is greater than the first width W1 of the first region 11. When the notch 61 is formed on any one of the two edges 13a and 13b in the width direction Y of the third region 13, the width 61W refers to a distance between the tip portion of the notch 61 and an edge on which the notch 61 is not formed. When a pair of notches 61 are formed on the edges 13a and 13b of both sides in the width direction Y of the third region 13 to face each other in the width direction Y, the width 61W refers to a distance between a pair of tip portions of the notches 61. A depth 61D of the notch 61 may be determined to satisfy a condition that the width 61W of the third region 13 reduced by the notch 61 is greater than the first width W1 of the first region 11.

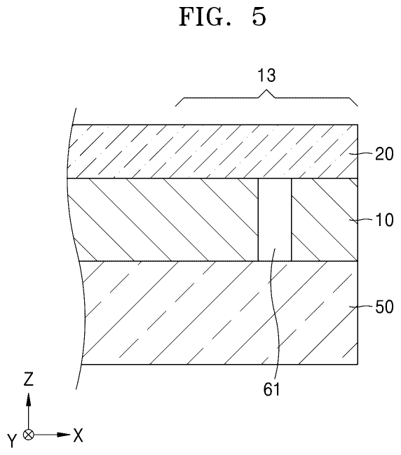

However, the thickness of the notch 61 is not limited to the description presented above. FIG. 5 is a side view of the notch 61 according to an example embodiment. Referring to FIG. 5, the thickness of the notch 61 may be the same as the thickness of the free layer 10. In other words, the notch 61 may be recessed from the upper surface of the free layer 10 to the lower surface of the free layer 10 in the thickness direction Z, and the upper surface of the spin orbit torque layer 50 may be exposed by the notch 61. When the notch 61 that is partially recessed in the free layer 10 in the thickness direction Z after forming the free layer 10, the notch 61 may be formed by an etching process. In this case, an etch mask may be necessary or may be needed. According to the present example embodiment, as the notch 61 may be formed together when forming the free layer 10, a separate etch mask for forming the notch 61 may not be necessary or may not be needed, and the manufacturing process cost may be reduced.

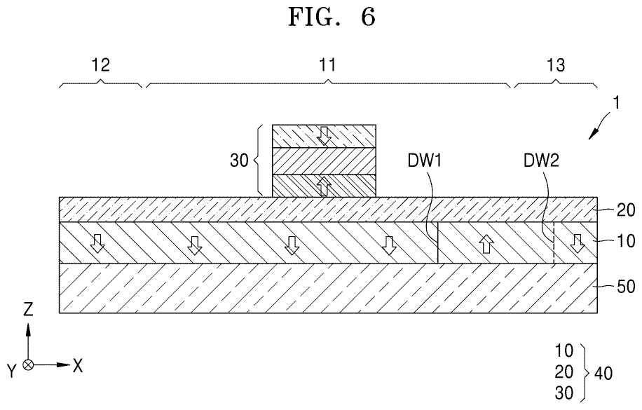

The magnetic memory device 1 may operate as a so-called racetrack memory in which the movable domain wall DW1 moves along the first region 11 depending on the direction of the current applied to the spin orbit torque layer 50. FIG. 6 illustrates a magnetically switched state in the magnetic memory device 1 according to an example embodiment. The operation of the magnetic memory device 1 is described with reference to FIGS. 1 and 6.

Referring to FIG. 1, the pinned layer 30 (e.g., the lower layer of the pinned layer 30) in contact with the tunnel barrier layer 20 has a magnetization direction in a +Z direction. The magnetization direction of the first region 11 of the free layer 10, that is, the area facing the pinned layer 30, is the +Z direction. In this case, the magnetization directions of the free layer 10 and the pinned layer 30 are the same as each other, and the tunneling magnetic resistance layer 40 has a low resistance value. The magnetic memory device 1 may be, for example, in a data “0” state. When a current over a threshold current is supplied to the spin orbit torque layer 50, the movable domain wall DW1 moves in a movement direction of conductive charges so that magnetic switching occurs in the first region 11 of the free layer 10. For example, as illustrated in FIG. 6, as the movable domain wall DW1 moves in the +X direction along the first region 11, the magnetization direction of the first region 11 of the free layer 10, that is, the area facing the pinned layer 30, is switched from the +Z direction to the −Z direction. The magnetization directions of the free layer 10 and the pinned layer 30 are opposite to each other, and the tunneling magnetic resistance layer 40 has a high resistance value. The magnetic memory device 1 is, for example, in a data “1” state. When a current over the threshold current in the opposite direction is supplied to the spin orbit torque layer 50, the movable domain wall DW1 moves in the −X direction along the first region 11, as illustrated in FIG. 1. The magnetization direction of the first region 11 of the free layer 10, that is, the area facing the pinned layer 30, may be switched to the +Z direction. Then, the magnetic memory device 1 may be returned to the data “0” state.

When the pinned domain wall DW2 moves to the first region 11 while the movable domain wall DW1 moves, an appropriate write operation may not be performed. According to some example embodiments of the disclosure, the pinned domain wall DW2 maintains a state of being fixed to the third region 13 by the pinning site 60. Accordingly, the appropriate write operation of the magnetic memory device 1 may be ensured or guaranteed, and a writing error rate (WER) may be reduced. According to the magnetic memory device 1 according to some example embodiments of the disclosure, as the free layer 10 does not need to have a magnetic field generation structure to form a magnetic domain and a domain wall therein, the structure of the magnetic memory device 1 may be simplified and miniaturized. Furthermore, as a domain wall and a magnetic domain may be formed in the free layer 10 by a simple initialization process of applying a pulse voltage to the free layer 10 and the spin orbit torque layer 50 within a magnetic field, the manufacturing cost of the magnetic memory device 1 may be reduced.

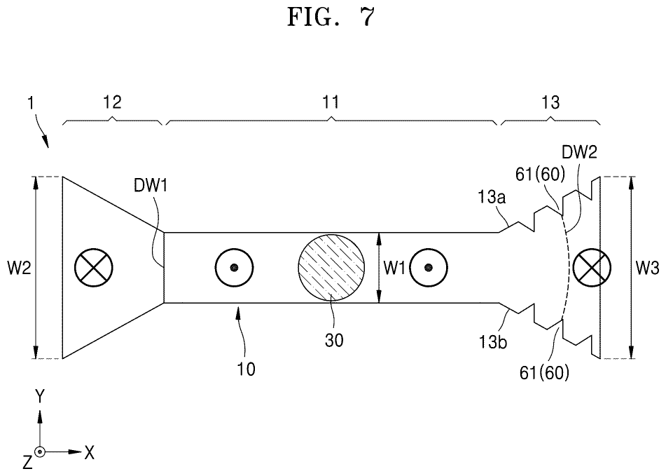

FIG. 7 is a schematic plan view of the magnetic memory device 1 according to an example embodiment. Referring to FIG. 7, a plurality of pinning sites 60 are arranged in the third region 13 of the free layer 10 in the longitudinal direction X. Each of the pinning sites 60 may include the notch 61 described in FIGS. 2, 4, and 5. Each of the pinning sites 60 may include a pair of notches 61 arranged to face each other in the width direction Y. A plurality of energy stabilization areas are formed in the third region 13 by the pinning sites 60, and the pinned domain wall DW2 may be stably fixed to the third region 13. Furthermore, during a write operation, the pinned domain wall DW2 is stably fixed by the pinning sites 60, and thus, fixing stability may be improved.

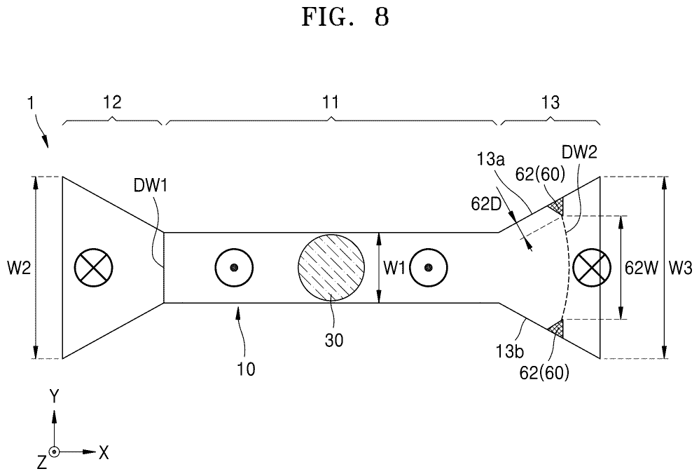

FIG. 8 is a schematic plan view of the magnetic memory device 1 according to an example embodiment. Referring to FIG. 8, the pinning site 60 may include a doping area 62. For example, the doping area 62 extends inwardly from the edge 13a on one side in the width direction Y of the third region 13. The doping area 62 is an area doped with impurities. The impurities may include a material which may erase a magnetic moment, for example, a nonmagnetic heavy element. The impurities may include, for example, at least one of Ta, W, Pt, or Au. The shape of the doping area 62 is not specially limited. As an example, the doping area 62 may have a notch shape extending inwardly in a direction perpendicular to the edge 13a on one side in the width direction Y of the third region 13.

As described above, the domain wall has higher energy as the length thereof increases. The impurities doped in the doping area 62 may erase the magnetic moment. Accordingly, as the pinned domain wall DW2 generated in the initialization process has a shorter length and a lower energy closer to the doping area 62, the energy is reduced or minimized in the doping area 62. Accordingly, when the pinned domain wall DW2 reaches near the doping area 62, the energy is stabilized so as no longer to move in the longitudinal direction X and fixed near the doping area 62. As the pinned domain wall DW2 is fixed using the doping area 62 that removes magnetic moment, without increasing the device resistance of the magnetic memory device 1, the pinned domain wall DW2 may be fixed to the third region 13.

The doping area 62 may be formed on at least one of the two edges 13a and 13b in the width direction Y of the third region 13. In other words, the doping area 62 may be formed on any one of the two edges 13a and 13b in the width direction Y of the third region 13, and as illustrated in FIG. 8, the doping area 62 may be formed as a pair of doping areas on the edges 13a and 13b of both sides in the width direction Y of the third region 13, respectively, to face each other in the width direction Y. By adopting a pair of the doping areas 62, the pinned domain wall DW2 may be more easily fixed.

The width 62W of the third region 13, which is reduced by the doping area 62, is greater than the first width W1 of the first region 11. When the doping area 62 is formed on any one of the two edges 13a and 13b in the width direction Y of the third region 13, the width 62W refers to a distance between the tip portion of the doping area 62 and an edge on which the doping area 62 is not formed. When a pair of doping areas 62 are formed on the edges 13a and 13b of both sides in the width direction Y of the third region 13 to face each other in the width direction Y, the width 62W refers to a distance between a pair of tip portions of the doping areas 62. A depth 62D of the doping area 62 may be determined to satisfy a condition that the width 62W of the third region 13 reduced by the doping area 62 is greater than the first width W1 of the first region 11.

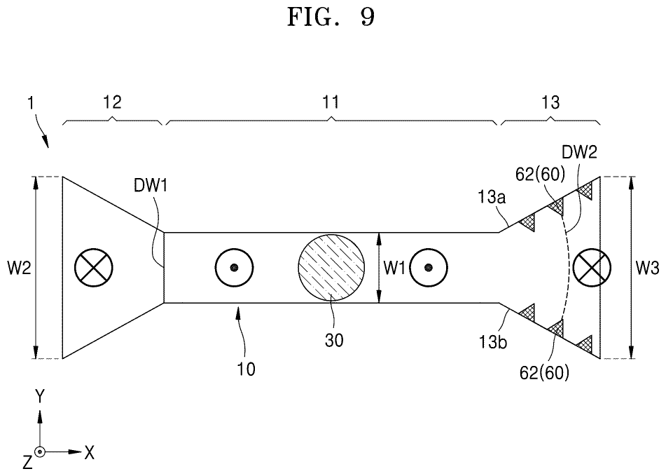

FIG. 9 is a schematic plan view of the magnetic memory device 1 according to an example embodiment. Referring to FIG. 9, a plurality of pinning sites 60 are arranged in the third region 13 of the free layer 10 in the longitudinal direction X. Each of the pinning sites 60 may include the doping area 62 described in FIG. 8. Each of the pinning sites 60 may include a pair of doping areas 62 arranged to face each other in the width direction Y. A plurality of magnetic moment erasure areas may be formed in the third region 13 by the pinning sites 60 so as to stably fix the pinned domain wall DW2 in the third region 13. Furthermore, during a write operation, as the pinned domain wall DW2 is stably fixed by the pinning sites 60, fixing stability may be improved.

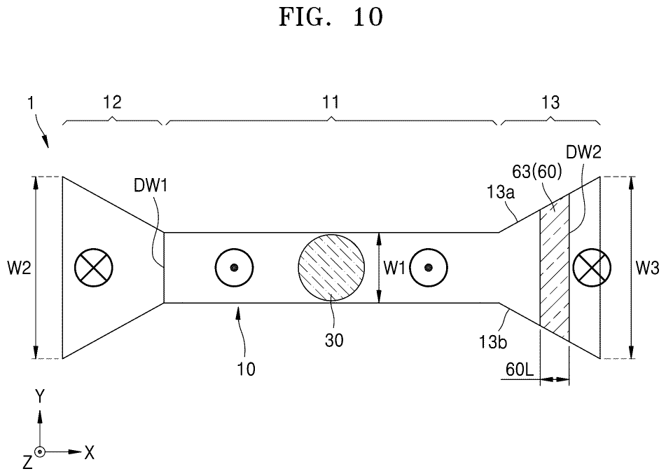

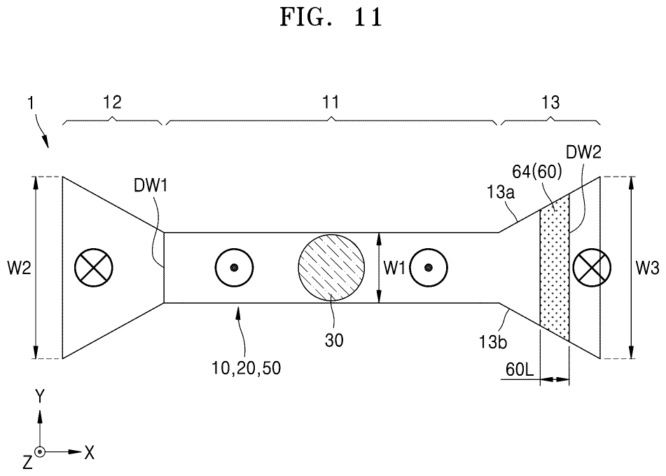

FIG. 10 is a schematic plan view of the magnetic memory device 1 according to an example embodiment. FIG. 11 is a schematic plan view of the magnetic memory device 1 according to an example embodiment. Referring to FIGS. 10 and 11, the pinning site 60 may be formed across the third region 13 of the free layer 10 in the width direction Y. The pinning site 60 may extend from the edge 13a of one side of the third region 13 to the edge 13b of the other side thereof. The pinning site 60 may have a length 60L in the longitudinal direction X. The length 60L of the pinning site 60, that is, the length of a recess portion 63 in a belt shape and the length of a doping area 64 for forming a belt described below, may be greater than or equal to the length of the pinned domain wall DW2. Considering that the length of the pinned domain wall DW2 is about 10 nm to about 100 nm, the length 60L of the pinning site 60 may be about 100 nm or more. The length 60L of the pinning site 60 may be equal to or less than the length (the length in the X direction) of the third region 13.

In an example embodiment, referring to FIG. 10, the pinning site 60 may include, for example, the recess portion 63 recessed from the upper surface of the free layer 10 to the lower surface thereof. In other words, the recess portion 63 may be recessed to the spin orbit torque layer 50, and the upper surface of the spin orbit torque layer 50 may be exposed by the recess portion 63. The recess portion 63 may be formed by etching a part of the third region 13 of the free layer 10 into a belt shape in the width direction Y.

In an embodiment, referring to FIG. 11, the pinning site 60 may be implemented by the doping area 64. The doping area 64 is an area doped with impurities. The impurities may include a material which may erase a magnetic moment, for example, a nonmagnetic heavy element. The impurities may include, for example, at least one of Ta, W, Pt, or Au.

The magnetization area of the third region 13 of the free layer 10 is isolated by the recess portion 63 of a belt shape or the doping area 64 of a belt shape. In other words, the free layer 10 (e.g., the magnetization of the third region 13) is partially erased by the recess portion 63 of a belt shape or the doping area 64 of a belt shape. The pinned domain wall DW2 generated in the initialization process described above reaches the recess portion 63 of a belt shape or the doping area 64 of a belt shape and vanishes. Accordingly, the depinning of the pinned domain wall DW2 may be avoided or prevented, a write error rate may be improved, and the thermal stability of the magnetic memory device 1 may be improved. The length 60L of the recess portion 63 of a belt shape or the doping area 64 of a belt shape may be determined to be sufficient to isolate the magnetization area of the third region 13 of the free layer 10.

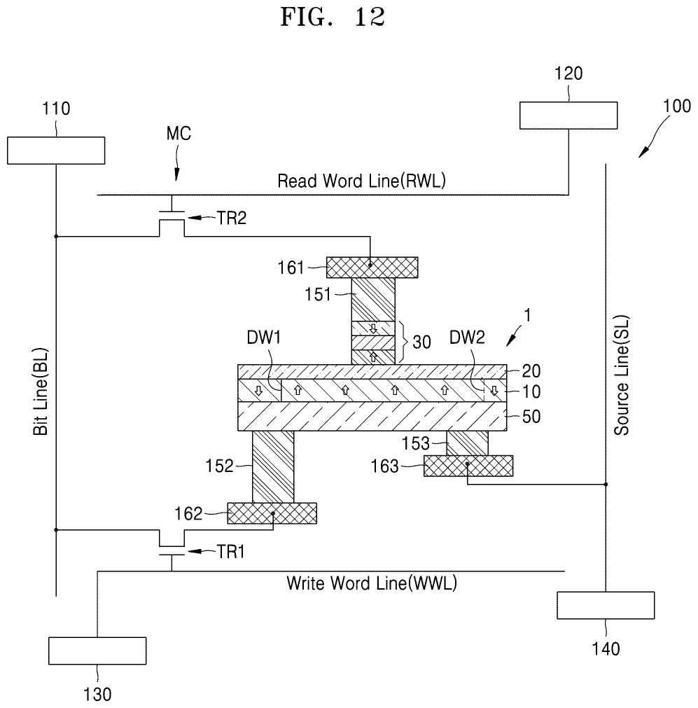

FIG. 12 is a schematic configuration view of a memory device 100 including the magnetic memory device 1 according to an example embodiment. Although FIG. 12 illustrates, for convenience of explanation, one memory cell MC, the memory device 100 may include a plurality of memory cells MCs. Referring to FIG. 12, a memory cell MC may include the magnetic memory device 1 and switching elements TR1 and TR2 connected to the magnetic memory device 1. The switching elements TR1 and TR2 may be thin film transistors. The memory cell MC may be connected between a bit line BL and a write word line WWL and a read word line RWL. The bit line BL and the write word line WWL and the read word line RWL may be arranged to intersect one another, and the memory cell MC may be disposed at an intersection thereof.

The bit line BL is electrically connected to the pinned layer 30 of the magnetic memory device 1 via the switching element TR2. In other words, the bit line BL is connected to a first source/drain electrode of the switching element TR2, and a second source/drain electrode of the switching element TR2 is connected to the pinned layer 30. The read word line RWL is connected to a gate of the switching element TR2. The bit line BL may be electrically connected to one end portion of the spin orbit torque layer 50 of the magnetic memory device 1, for example, an area corresponding to the second region 12 of the free layer 10, via the switching element TR1. The bit line BL is connected to a first source/drain electrode of the switching element TR1, and a second source/drain electrode of the switching element TR1 is electrically connected to the one end portion of the spin orbit torque layer 50 of the magnetic memory device 1, for example, the area corresponding to the second region 12 of the free layer 10. The write word line WWL may be connected to a gate of the switching element TR1. The other end portion of the spin orbit torque layer 50 of the magnetic memory device 1, for example, the area corresponding to the third region 13 of the free layer 10, is electrically connected to a source line SL.

A bit line driver 110 applies a current to a plurality of bit lines BLs that are connected to the memory cells MCs, respectively. A read word line driver 120 applies a current to a plurality of read word lines RWLs that are connected to the memory cells MCs, respectively. A write word line driver 130 applies a current to a plurality of write word lines WWLs that are connected to the memory cells MCs, respectively. A source line driver 140 applies a current to a plurality of source lines SLs that are connected to the memory cells MCs, respectively.

A conductive pad 151 for electrical connection with the switching element TR2 is provided on the pinned layer 30 of the magnetic memory device 1, and the conductive pad 151 is connected to the switching element TR2 through a wiring layer 161 of the memory device 100. A conductive pad 152 is provided on the spin orbit torque layer 50 of the magnetic memory device 1 and is electrically connected to the switching element TR1 through a wiring layer 162 of the memory device 100, and the conductive pad 153 is provided on the spin orbit torque layer 50 of the magnetic memory device 1 and is electrically connected to the source line SL through a wiring layer 163 of the memory device 100.

A write current may be applied to the memory cell MC through the write word line WWL and the bit line BL. For example, a write current IW over a threshold current may flow through a path between the conductive pads 152 and 153 on both sides of the spin orbit torque layer 50. Then, the magnetization direction of the free layer 10 may be changed in the +Z direction or in the −Z direction depending on the direction of the current applied to the spin orbit torque layer 50. Furthermore, a read current may be applied to the magnetic memory device 1 through the read word line RWL and the bit line BL. The read current may flow along a path between the conductive pad 151 of the pinned layer 30 and the conductive pad 152 or the conductive pad 153 of the spin orbit torque layer 50. For example, a read current lower than the threshold current is applied through the conductive pad 151, and by measuring a current flowing between the spin orbit torque layer 50 and the bit line BL or the source line SL, a resistance value of the magnetic memory device 1 may be read.

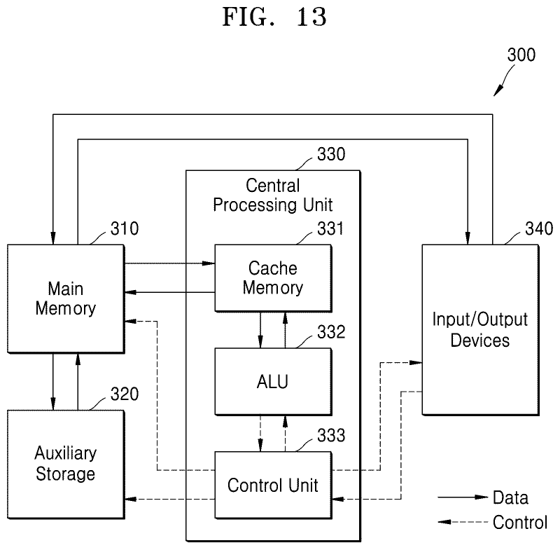

The memory device 100 described above may be used to store data in various electronic apparatuses. FIG. 13 is a conceptual view schematically showing a device architecture applicable to an electronic apparatus 300 according to an example embodiment. Referring to FIG. 13, the electronic apparatus 300 may include a main memory 310, an auxiliary storage 320, a central processing unit (CPU) 330, and input/output devices 340. The CPU 330 may include a cache memory 331, an arithmetic logic unit (ALU) 332, and a control unit 333. The cache memory 331 may include a static random access memory (SRAM). The main memory 310 may include a DRAM device, and the auxiliary storage 320 may include a memory device 100 according to an example embodiment. In some example embodiments, the cache memory 331, the main memory 310, and the auxiliary storage 320 may all include the memory device 100 of FIG. 12. In some cases, the electronic apparatus 300 may be implemented in the form in which computing unit devices and memory unit devices are adjacent to each other in one chip without distinction of the sub-units described above.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

According to the magnetic memory device according to the example embodiment described above, a magnetic generation structure may be omitted so that a scalable magnetic memory device with a simple structure may be implemented. Furthermore, as a domain wall that is not used for a write operation may be fixed to the outside of the read and write area, the write error rate may be improved (e.g., reduced). Furthermore, the magnetic memory device according to some example embodiments may be applied to a racetrack memory with a fast operating speed and a low consumption power.

It should be understood that the magnetic memory device including a tunneling magnetic resistance layer described above, and the memory device including the magnetic memory device, should be considered in a descriptive sense only and not for purposes of limitation. Descriptions of features or aspects within each example embodiment should typically be considered as available for other similar features or aspects in other example embodiments. While some example embodiments have been described with reference to the figures, it will be understood by those of ordinary skill in the art that various changes in form and details may be made therein without departing from the spirit and scope as defined by the following claims.

What is claimed is:

1. A magnetic memory device comprising:
a free layer including a movable domain wall and a pinned domain wall;
a tunnel barrier layer;
a pinned layer on the tunnel barrier layer, the pinned layer configured to form a magnetic tunneling junction with the free layer and the tunnel barrier layer;
a spin orbit torque layer arranged at an opposite side to the tunnel barrier layer with respect to the free layer and configured to change a magnetization direction of the free layer; and
a domain wall pinning site configured to fix the pinned domain wall,
wherein the free layer comprises a first region, a second region, and a third region, the first region being an area having a first width and in which the movable domain wall moves, the second and third regions extending from both end portions of the first region, respectively, the second and third regions having a second width and a third width, respectively, the second and third widths being greater than the first width, and
the domain wall pinning site is in the third region of the free layer.

2. The magnetic memory device of claim 1, wherein the domain wall pinning site comprises a notch recessed from an edge on at least one side in a width direction of the third region.

3. The magnetic memory device of claim 2, wherein the notch comprises a pair of notches on edges of both sides in the width direction of the third region and the pair of notches face each other in the width direction.

4. The magnetic memory device of claim 2, wherein the spin orbit torque layer is exposed by the notch.

5. The magnetic memory device of claim 1, wherein the domain wall pinning site comprises a doping area extending inwardly from an edge on at least one side in a width direction of the third region and doped with impurities.

6. The magnetic memory device of claim 5, wherein the impurities comprise a nonmagnetic heavy element.

7. The magnetic memory device of claim 6, wherein the impurities comprise at least one of Ta, W, Pt, or Au.

8. The magnetic memory device of claim 6, wherein the doping area comprises a pair of doping areas on edges of both sides in the width direction of the third region and the pair of doping areas face each other in the width direction.

9. The magnetic memory device of claim 1, wherein the domain wall pinning site comprises a plurality of domain wall pinning sites and the plurality of domain wall pinning sites are in the third region along a longitudinal direction.

10. The magnetic memory device of claim 9, wherein the plurality of domain wall pinning sites comprise at least one of
a notch recessed from an edge on at least one side in a width direction of the third region, or
a doping area extending inwardly from an edge on at least one side in the width direction of the third region and doped with impurities.

11. The magnetic memory device of claim 1, wherein the domain wall pinning site comprises a recess portion, and the recess portion is across the third region in a width direction and recessed to the spin orbit torque layer.

12. The magnetic memory device of claim 1, wherein the domain wall pinning site comprises a doping area, and the doping area is across the third region in a width direction and doped with impurities including a nonmagnetic heavy element.

13. A method of initializing a magnetic memory device, the method comprising:
preparing the magnetic memory device, the magnetic memory device including a free layer, a tunnel barrier layer, a pinned layer on the tunnel barrier layer and configured to form a magnetic tunneling junction with the free layer and the tunnel barrier layer, a spin orbit torque layer at an opposite side of the tunnel barrier layer with respect to the free layer and configured to change a magnetization direction of the free layer, and a domain wall pinning site, wherein the free layer comprises a first region, a second region, and a third region, the first region being an area having a first width, the second and third regions extending from both end portions of the first region, respectively, the second and third regions having a second width and a third width, respectively, the second and third widths being greater than the first width, and the domain wall pinning site is in the third region of the free layer;
forming a movable domain wall between the first region and the second region by applying a pulse voltage to the free layer and the spin orbit torque layer within a magnetic field; and
fixing a pinned domain wall to the domain wall pinning site.

14. The method of claim 13, wherein the pulse voltage is applied multiple times.

15. A memory device comprising:
a plurality of memory cells, each comprising a magnetic memory device and a switching element connected to the magnetic memory device,
wherein the magnetic memory device includes
a free layer including a movable domain wall and a pinned domain wall,
a tunnel barrier layer,
a pinned layer on the tunnel barrier layer and configured to form a magnetic tunneling junction with the free layer and the tunnel barrier layer, and
a spin orbit torque layer arranged at an opposite side of the tunnel barrier layer with respect to the free layer and configured to change a magnetization direction of the free layer,
wherein the free layer comprises a first region, a second region, and a third region, the first region being an area having a first width and in which the movable domain wall moves, the second and third regions extending from both end portions of the first region, respectively, the second and third regions having a second width and a third width, respectively, the second and third width being greater than the first width, and
a domain wall pinning site is configured to fix the pinned domain wall to the third region of the free layer.

16. The memory device of claim 15, wherein the domain wall pinning site comprises a notch recessed in a width direction from an edge on at least one side in the width direction of the third region.

17. The memory device of claim 15, wherein the domain wall pinning site comprises a doping area extending inwardly from an edge on at least one side in a width direction of the third region and doped with impurities including a nonmagnetic heavy element.

18. The memory device of claim 15, wherein the domain wall pinning site comprises a plurality of domain wall pinning sites along a longitudinal direction of the third region.

19. The memory device of claim 15, wherein the domain wall pinning site comprises a recess portion, and the recessed portion is across the third region in a width direction and recessed to the spin orbit torque layer.

20. The memory device of claim 15, wherein the domain wall pinning site comprises a doping area, and the doped area is across the third region in a width direction and doped with impurities including a nonmagnetic heavy element.
